(19) United States
(12) Patent Application Publication
(10) Pub. No.: US 2025/0006798 A1
(43) Pub. Date: Jan. 2, 2025

(54) NITRIDE SEMICONDUCTOR DEVICE AND MANUFACTURING METHOD THEREFOR

(71) Applicant: Panasonic Intellectual Property Management Co., Ltd., Osaka (JP)

(72) Inventors: Hideyuki OKITA, Osaka (JP); Masahiro HIKITA, Hyogo (JP); Yasuhiro UEMOTO, Shiga (JP)

(21) Appl. No.: 18/708,941

(22) PCT Filed: Oct. 31, 2022
(86) PCT No.: PCT/JP2022/040725

§ 371 Date: May 9, 2024

(30) Foreign Application Priority Data
Dec. 2, 2021 (JP) 2021-195858

(51) Int. Cl. H01L 29/20; H01L 21/02; H01L 21/265; H01L 21/324; H01L 29/207; H01L 29/45; H01L 29/66; H01L 29/778

(52) U.S. Cl. CPC H01L 29/2003; H01L 21/0254; H01L 21/26546; H01L 21/3245; H01L 29/207; H01L 29/452; H01L 29/66462; H01L 29/7786

(57) ABSTRACT

A nitride semiconductor device includes: a substrate; a first nitride semiconductor layer provided over the substrate; a second nitride semiconductor layer that is on the first nitride semiconductor layer and includes a band gap larger than a band gap of the first nitride semiconductor layer; and a third nitride semiconductor layer that is on the second nitride semiconductor layer and includes a band gap larger than the band gap of the first nitride semiconductor layer. The second nitride semiconductor layer includes a damaged region in which an n-type impurity is selectively added by ion implantation. A diffusion region in which the n-type impurity is diffused is present in a vicinity of the damaged region. The nitride semiconductor device further includes: an ohmic electrode provided above the damaged region. The ohmic electrode is in ohmic contact with the diffusion region.

### CROSS-REFERENCE OF RELATED APPLICATIONS

This application is the U.S. National Phase under 35 U.S.C. § 371 of International Patent Application No. PCT/JP2022/040725, filed on Oct. 31, 2022, which in turn claims the benefit of Japanese Patent Application No. 2021-195858, filed on Dec. 2, 2021, the entire disclosure of which Applications are incorporated by reference herein.

### TECHNICAL FIELD

The present disclosure relates to a nitride semiconductor device and a manufacturing method therefor.

### BACKGROUND ART

Group III nitride semiconductors have high dielectric breakdown voltages due to their wide band gaps. In addition, it is possible to easily form a heterostructure such as AlGaN/GaN, and due to (i) the piezoelectric charge generated from the difference in lattice constant between AlGaN and GaN and (ii) the difference in band gap, high mobility and high concentration electron channels (two-dimensional electron gas) can be generated on the GaN layer side of the AlGaN/GaN interface. Controlling this two-dimensional electron gas makes it possible to form a high electron mobility transistor (HEMT). Due to these characteristics of high breakdown voltage, high speed, and large current, group III nitride semiconductors have been applied to electronic devices such as field effect transistors (FETs) for power use and diodes.

The manufacturing method for a semiconductor device illustrated in FIG. 1 to FIG. 5 of Patent Literature (PTL) 1 includes implanting ions at a high temperature of 300° C. or higher into a base layer; activation annealing the base layer; and forming a first epitaxial growth layer on the base layer.

According to PTL 1, conventionally, when room temperature ion implantation is performed and epitaxial growth is attempted on it, the crystal of the epitaxial growth layer becomes amorphous, and even if annealed at a high temperature, it is said that crystallinity is never completely restored. In addition, it is said that further epitaxial growth tends to produce a rough surface and defects inside the crystal, and electrical leakage current is also likely to occur. However, it is said that in the manufacturing method of PTL 1, by performing high-temperature ion implantation, the surface shape of the base layer after ion implantation can be improved, and the surface of the epitaxial growth layer grown thereon can also be made smooth without becoming rough. It is also said that the presence of the cap layer can prevent ions and atoms from detaching from the base layer during annealing.

### CITATION LIST

### Patent Literature

[PTL 1] Japanese Unexamined Patent Application Publication No. 2003-133240

### SUMMARY OF INVENTION

### Technical Problem

However, in the manufacturing method and structure described in PTL 1, the surface of the epitaxial layer decomposes in the activation annealing step. This causes the crystal structure and stoichiometry to collapse, which in turn causes increased gate leakage. In addition, as shown in FIG. 3 of PTL 1, even if the activation annealing step is performed after forming the cap layer, the crystal structure and stoichiometry of the surface of the cap layer will collapse, which causes increased gate leakage in any case. In addition, since it is necessary to take out the wafer from the crystal growth apparatus once during activation annealing, gate leakage increases due to effects such as oxidation of the crystal surface and pile-up of carbon, silicon, and the like.

### Solution to Problem

Therefore, a nitride semiconductor device according to one aspect of the present disclosure includes: a substrate; a first nitride semiconductor layer provided over the substrate; a second nitride semiconductor layer that is on the first nitride semiconductor layer and includes a band gap larger than a band gap of the first nitride semiconductor layer; and a third nitride semiconductor layer that is on the second nitride semiconductor layer and includes a band gap larger than the band gap of the first nitride semiconductor layer, wherein the second nitride semiconductor layer includes a damaged region in which an n-type impurity is selectively added by ion implantation, a diffusion region in which the n-type impurity is diffused is present in a vicinity of the damaged region, and the nitride semiconductor device further comprises: an ohmic electrode provided above the damaged region, and the ohmic electrode is in ohmic contact with the diffusion region.

### Advantageous Effects of Invention

In the nitride semiconductor device according to the present disclosure, it is possible to increase drain current by reducing contact resistance, reduce on-resistance, and reduce gate leakage.

### BRIEF DESCRIPTION OF DRAWINGS

FIG. 1 is a cross-sectional view showing a cross-sectional structure of a nitride semiconductor device according to an embodiment.

FIG. 2 is a diagram showing a cross-sectional structure of a nitride semiconductor device according to Variation 1 of the embodiment.

FIG. 3 is a diagram showing a cross-sectional structure of a nitride semiconductor device according to Variation 2 of the embodiment.

FIG. 4 is a diagram showing a cross-sectional structure of a nitride semiconductor device according to Variation 3 of the embodiment.

FIG. 5 is a diagram showing a cross-sectional structure of a nitride semiconductor device according to Variation 4 of the embodiment.

FIG. 6A is a cross-sectional view showing a cross-sectional structure in one step of Example 1 of a manufacturing method for a nitride semiconductor device according to the embodiment.

FIG. 6B is a cross-sectional view showing a cross-sectional structure in one step of Example 1 of the manufacturing method for a nitride semiconductor device according to the embodiment.

FIG. 6C is a cross-sectional view showing a cross-sectional structure in one step of Example 1 of a manufacturing method for a nitride semiconductor device according to the embodiment.

FIG. 6D is a cross-sectional view showing a cross-sectional structure in one step of Example 1 of a manufacturing method for a nitride semiconductor device according to the embodiment.

FIG. 6E is a cross-sectional view showing a cross-sectional structure in one step of Example 1 of the manufacturing method for a nitride semiconductor device according to the embodiment.

FIG. 7A is a cross-sectional view showing a cross-sectional structure in one step of Example 2 of the manufacturing method for a nitride semiconductor device according to the embodiment.

FIG. 7B is a cross-sectional view showing a cross-sectional structure in one step of Example 2 of the manufacturing method for a nitride semiconductor device according to the embodiment.

FIG. 7C is a cross-sectional view showing a cross-sectional structure in one step of Example 2 of the manufacturing method for a nitride semiconductor device according to the embodiment.

FIG. 7D is a cross-sectional view showing a cross-sectional structure in one step of Example 2 of the manufacturing method for a nitride semiconductor device according to the embodiment.

FIG. 7E is a cross-sectional view showing a cross-sectional structure in one step of Example 2 of the manufacturing method for a nitride semiconductor device according to the embodiment.

FIG. 8A is a cross-sectional view showing a cross-sectional structure in one step of Example 3 of a manufacturing method for a nitride semiconductor device according to the embodiment.

FIG. 8B is a cross-sectional view showing a cross-sectional structure in one step of Example 3 of the manufacturing method for a nitride semiconductor device according to the embodiment.

FIG. 8C is a cross-sectional view showing a cross-sectional structure in one step of Example 3 of the manufacturing method for a nitride semiconductor device according to the embodiment.

FIG. 8D is a cross-sectional view showing a cross-sectional structure in one step of Example 3 of the manufacturing method for a nitride semiconductor device according to the embodiment.

FIG. 8E is a cross-sectional view showing a cross-sectional structure in one step of Example 3 of the manufacturing method for a nitride semiconductor device according to the embodiment.

FIG. 9 is a regrowth profile including in-situ activation annealing of the nitride semiconductor device according to the embodiment.

### DESCRIPTION OF EMBODIMENTS

Hereinafter, a nitride semiconductor device according to an embodiment will be specifically described with reference to the drawings. It should be noted that each of the embodiments described below represents a specific example of the present disclosure. The numerical values, shapes, materials, components, arrangement positions and connection forms of the components, and the like shown in the following embodiments are merely examples, and are not intended to limit the present disclosure. In addition, among the components in the following embodiments, the components not described in the independent claims are described as arbitrary components.

### Embodiment

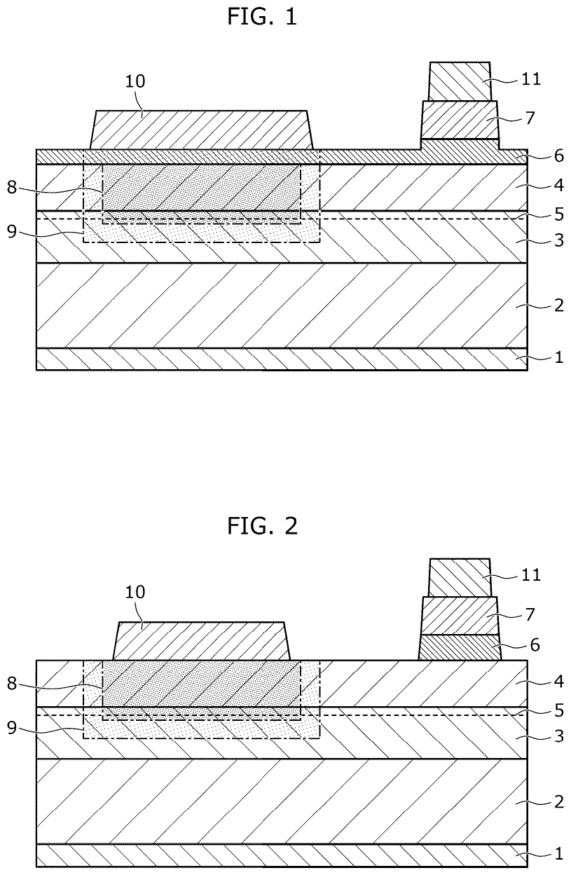

FIG. 1 shows a cross-sectional structural diagram of a nitride semiconductor device according to an embodiment, in which an ohmic electrode is in ohmic contact with a diffusion region.

The present structure includes suitable buffer layer 2 (for example, a single layer or multiple layers of group III nitride semiconductors, such as GaN, AlGaN, AlN, InGaN, InN, AlInGaN, and the like) on suitable Si substrate 1 (alternatively, a substrate such as Sapphire, SiC, GaN, AlN, and the like). On buffer layer 2, first nitride semiconductor layer 3 consisting of GaN (alternatively, for example, InGaN, InN, AlGaN, AlInGaN, and the like, which are group III nitride semiconductors) is included. On first nitride semiconductor layer 3, second nitride semiconductor layer 4 consisting of AlGaN (alternatively, for example, GaN, InGaN, AlGaN, AlN, AlInGaN, and the like, which are group III nitride semiconductors) is included. Second nitride semiconductor layer 4 includes a band gap larger than that of first nitride semiconductor layer 3, and is in direct contact with first nitride semiconductor layer 3. When second nitride semiconductor layer 4 consists of AlGaN and first nitride semiconductor layer 3 consists of GaN, due to (i) the piezoelectric charge generated by the difference in lattice constants between AlGaN and GaN and (ii) the difference in band gap, a high concentration of two-dimensional electron gas 5 is generated on the side of first nitride semiconductor layer (channel layer) 3 near the interface between second nitride semiconductor layer 4 and first nitride semiconductor layer 3.

On second nitride semiconductor layer 4, third nitride semiconductor layer 6 consisting of AlGaN (alternatively, for example, GaN, InGaN, AlGaN, AlN, AlInGaN, and the like, which are group III nitride semiconductors) is included. Third nitride semiconductor layer 6 includes a band gap larger than that of first nitride semiconductor layer 3 and is in direct contact with second nitride semiconductor layer 4. It should be noted that it is desirable that second nitride semiconductor layer 4 is a nitride semiconductor containing Al to withstand high temperatures and decomposition by etching gases such as hydrogen when third nitride semiconductor layer 6 is formed on first nitride semiconductor layer 3 by metal organic vapor deposition (MOCVD) method or the like.

In addition, it is desirable that third nitride semiconductor layer 6 is a nitride semiconductor containing Al to withstand thermal decomposition during activation annealing at the high temperatures described later, and also to withstand decomposition by high temperatures and etching gases such as hydrogen when formed on second nitride semiconductor layer 4 by metal organic chemical vapor deposition (MOCVD) method or the like.

It is desirable that two-dimensional electron gas is not formed at the interface with second nitride semiconductor layer 4 directly under third nitride semiconductor layer 6, as this may cause gate leakage when a field effect transistor is formed. For that reason, it is desirable that the band gap of third nitride semiconductor layer 6 is equal to or smaller than the band gap of second nitride semiconductor layer 4. In addition, when third nitride semiconductor layer 6 is, for example, made of AlGaN, the band gap is smaller than that of second nitride semiconductor layer 4, which has also the effect of lowering the Al composition and improving crystallinity.

Second nitride semiconductor layer 4 includes damaged region 8 formed by ion implantation from the surface side. In damaged region 8, Si (alternatively, Ge and the like), which is an n-type impurity, is added by ion implantation, and the crystal lattice is collapsed due to the ion implantation damage, making it somewhat amorphous-like. By adding this n-type impurity, damaged region 8 becomes a low-resistance nitride semiconductor, which helps reduce contact resistance and sheet resistance.

This damaged region 8 may remain within second nitride semiconductor layer 4 in the depth direction, or may reach first nitride semiconductor layer 3 as shown in FIG. 1. From the viewpoint of reducing the contact resistance of the nitride semiconductor device and reducing the sheet resistance from ohmic electrode 10 to the two-dimensional electron gas, it is desirable that two-dimensional electron gas 5 in first nitride semiconductor layer 3 is reached. It is desirable that the n-type impurity implanted into damaged region 8 is highly concentrated because the ions are implanted for the purpose of obtaining a low-resistance nitride semiconductor layer. Specifically, it is desirable that the concentration is 1E19 cm⁻³ or higher, and it is desirable that the peak concentration is 1E20 cm⁻³ or higher.

Diffusion region 9 is provided in the vicinity of damaged region 8. Diffusion region 9 is formed by diffusion of the n-type impurity added by ion implantation into damaged region 8 into the surrounding area by activation annealing at a high temperature of 1100° C. or higher in an MOCVD chamber (in-situ) immediately after third nitride semiconductor layer 6 is formed on second nitride semiconductor layer 4 by MOCVD method or the like. Therefore, diffusion region 9 is provided in all nitride semiconductor layers on the top, bottom, left, and right that are in contact with damage region 8, that is, in all of first nitride semiconductor layer 3, second nitride semiconductor layer 4, and third nitride semiconductor layer 6 in FIG. 1. When the bottom surface of damaged region 8 stops in the middle of second nitride semiconductor layer 4 (not shown), the lower end of diffusion region 9 may stop in second nitride semiconductor layer 4. From the viewpoint of reducing the contact resistance of the nitride semiconductor device and reducing the sheet resistance from the ohmic electrode to the two-dimensional electron gas, it is desirable that two-dimensional electron gas 5 of first nitride semiconductor layer 3 is reached from the inside of second nitride semiconductor layer 4. This results in a nitride semiconductor device with lower on-resistance.

It should be noted that diffusion region 9 is defined as a region that is in contact with damaged region 8 and in which an n-type impurity is diffused from damaged region 8. Here, more specifically, it may be a region where the concentration of an n-type impurity is 1E18 cm⁻³ or more. In addition, since the n-type impurity concentration in diffusion region 9 is diffused from damaged region 8, the n-type impurity concentration in diffusion region 9 is inevitably lower than that in damaged region 8. Specifically, since it is desirable that the peak concentration of damaged region 8 is 1E20 cm⁻³ or more, the n-type impurity concentration of diffusion region 9 is 1E20 cm⁻³ or less. This makes diffusion region 9 a nitride semiconductor with lower resistance, which helps reduce contact resistance and sheet resistance.

Diffusion region 9 has no or very little ion implantation damage in the downward and lateral directions among the upper, lower, left, and right sides that are in contact with damaged region 8. In addition, regarding third nitride semiconductor layer 6 located in the upper direction, Since third nitride semiconductor layer 6 is epitaxially grown by metal organic chemical vapor deposition (MOCVD) method or the like on top of damaged region 8, where the crystal lattice has collapsed and become slightly amorphous-like due to ion implantation damage, the crystallinity of diffusion region 9 directly above damaged region 8 is slightly poor.

Here, the reason why damaged region 8 is not a completely amorphous structure but a slightly amorphous-like structure with better crystallinity is that trimethylgallium (TMG) and trimethylaluminum (TMA), which are Group III raw materials, ammonia, which is a Group V raw material, and nitrogen and hydrogen, which are carrier gases, are supplied from the surface of damaged region 8 in the process of forming third nitride semiconductor layer 6 on diffusion region 9, thereby restoring the crystallinity in damaged region 8 to some extent. For that reason, the crystallinity of third nitride semiconductor layer 6, which grows directly above damaged region 8 whose crystallinity has been restored, is further improved. Furthermore, immediately after forming third nitride semiconductor layer 6, activation annealing is performed at a high temperature of 1100° C. or higher while flowing a gas such as ammonia, which is a group V raw material, or nitrogen, in an MOCVD chamber (in-situ), so that the slightly amorphous-like crystallinity of damaged region 8 can be further restored, and the crystallinity of third nitride semiconductor layer 6 directly above it can also be further restored. In addition, as mentioned above, it is desirable that third nitride semiconductor layer 6 is a nitride semiconductor containing Al in order to withstand thermal decomposition during this activation annealing.

In FIG. 1, ohmic electrode 10 is provided on third nitride semiconductor layer 6 on damaged region 8. Ohmic electrode 10 consists of an electrode made of one or a combination of two or more metals such as Ti, Al, Mo, and Hf that make ohmic contact with the nitride semiconductor layer. Ohmic electrode 10 is in direct contact with diffusion region 9 in third nitride semiconductor layer 6 and is electrically connected to two-dimensional electron gas 5. Since diffusion region 9 in third nitride semiconductor layer 6 directly above damaged region 8 has little crystal damage, the contact resistance of ohmic electrode 10 becomes small. In addition, the end of ohmic electrode 10 may also come into ohmic contact with diffusion region 9, which has very good crystallinity and is not directly above damaged region 8, so that the contact resistance is further reduced in that case.

The operation of this structure will be explained. By applying a positive voltage to ohmic electrode 10, a current flows into two-dimensional electron gas 5 via diffusion region 9 with which ohmic electrode 10 is in contact, and possibly further via damage region 8.

The effects of this structure will be explained. By using this structure, the contact resistance of ohmic electrode 10 is reduced, and the sheet resistance from ohmic electrode 10 to two-dimensional electron gas 5 is also reduced, resulting in a significant reduction in on-resistance and a significant increase in maximum drain current. In addition, since deterioration of crystallinity is kept to a minimum, gate leakage current can also be reduced.

### (Variation 1)

Next, FIG. 2 shows a cross-sectional structural diagram of a nitride semiconductor device according to Variation 1 of the embodiment, in which an ohmic electrode is ohmic contact with a damaged region. In FIG. 2, third nitride semiconductor layer 6 directly above damaged region 8 is completely removed, and ohmic electrode 10 is in direct ohmic contact with damaged region 8.

By using this variation, in addition to the effects of the embodiment, although some damage remains in damaged region 8, since it contains a high concentration of n-type impurity, the contact resistance, and the sheet resistance from ohmic electrode 10 to two-dimensional electron gas 5 can be further reduced.

### (Variation 2)

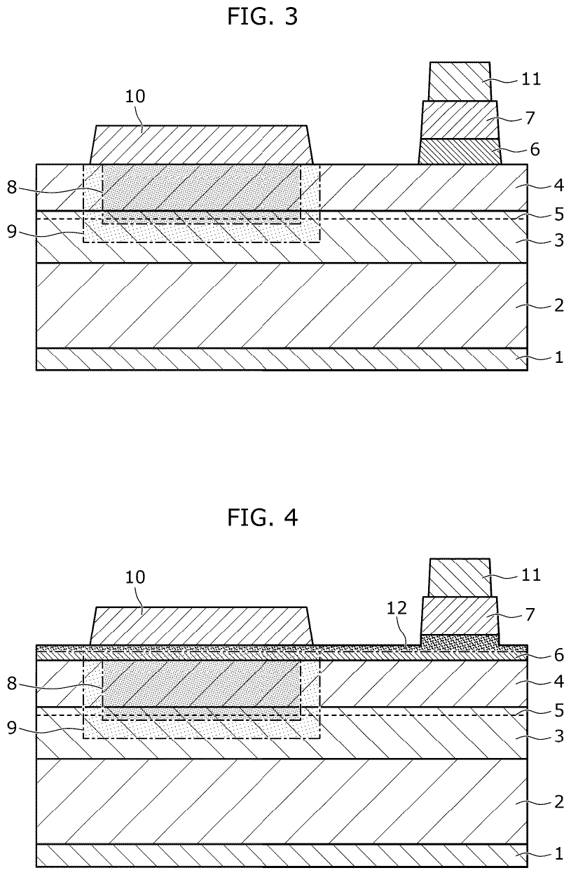

Next, FIG. 3 shows a cross-sectional structural diagram of a nitride semiconductor device according to Variation 2 of the embodiment, in which an ohmic electrode is ohmic contact with both a diffusion region and a damaged region. In FIG. 3, third nitride semiconductor layer 6 directly above damaged region 8 is completely or partially removed so that ohmic electrode 10 is in direct ohmic contact with both damaged region 8 and diffusion region 9.

By using this variation, in addition to the effects of the embodiment and the effects of Variation 1, since ohmic electrode 10 is ohmic contact with both damaged region 8, which contains high concentration of the n-type impurity and has low resistance, and diffusion region 9, which has very good crystallinity and low resistance, the contact resistance, and the sheet resistance from ohmic electrode 10 to two-dimensional electron gas 5 can be further reduced.

It should be noted that the contact resistance can be reduced by contacting ohmic electrode 10 with as much nitride semiconductor layer with low resistance as possible. For this reason, it is desirable that the electrode end of ohmic electrode 10 is located inside the end of damaged region 8 (FIG. 2) or inside diffusion region 9 (FIG. 3). Of course, the electrode end of ohmic electrode 10 may be located outside the end of damaged region 8 (not shown).

### (Variation 3)

Next, FIG. 4 shows a cross-sectional structural diagram of a nitride semiconductor device according to Variation 3 of the embodiment, in which the ohmic electrode is ohmic contact with the diffusion region, the damaged region, or both, and third nitride semiconductor layer includes the diffusion region of a p-type impurity.

In the embodiment, the nitride semiconductor device includes gate layer 7 that is selectively formed on third nitride semiconductor layer 6 continuously in an MOCVD chamber (in-situ) after forming third nitride semiconductor layer 6 and activation annealing. Gate layer 7 contains a p-type impurity (such as Mg, Zn, and C) consisting of p-GaN, which may be, for example, p-InGaN, p-InN, p-AlGaN, p-AlInGaN or the like which is a group III nitride semiconductor (see also FIG. 1 to FIG. 5). The p-type impurity concentration of gate layer 7 is doped to 1E19 cm⁻³ or more, and to 5E19 cm⁻³ or more, if possible, to make it p-type. Gate layer 7 is formed by forming p-GaN on third nitride semiconductor layer 6, forming a resist pattern using a known lithography method, and performing selective dry etching using inductively coupled plasma reactive ion etching (ICP-RIE) method or the like, which will be described in detail in the manufacturing method shown later. Even if selective dry etching is performed, the selectivity is not infinite, so over-etching of several nm to several tens of nm is allowed as shown in FIG. 1 to FIG. 5. For example, when the regrowth thickness of third nitride semiconductor layer 6 is about 20 nm, over-etching may be stopped in the middle of third nitride semiconductor layer 6 as shown in FIG. 1 and FIG. 4. Alternatively, as shown in FIG. 2 and FIG. 3, third nitride semiconductor layer 6 other than directly under gate layer 7 may be completely removed by over-etching by about 20 nm. Furthermore, over-etching may be applied to completely dig into the middle of second nitride semiconductor layer 4 (not shown). By completely removing third nitride semiconductor layer 6 by over-etching as shown in FIG. 2 and FIG. 3, it becomes possible for ohmic electrode 10 to come into direct ohmic contact with damaged region 8, as described above.

It should be noted that after the growth of third nitride semiconductor layer 6, by continuously forming gate layer 7 containing a p-type impurity (such as Mg, Zn, and C) consisting of p-GaN, the p-type impurity is diffused into third nitride semiconductor layer 6 to provide p-type impurity diffusion region 12 as shown in FIG. 4. When the p-type impurity is Mg and the p-type impurity concentration in gate layer 7 is 5E19 cm⁻³ or more, the p-type impurity concentration in p-type impurity diffusion region 12 is 5E19 cm⁻³ or less due to diffusion. Here, p-type impurity diffusion region 12 is defined as a region where the p-type impurity concentration is 1E18 cm⁻³ or higher. Depending on the growth conditions of gate layer 7 and the activation annealing conditions, the depth of p-type impurity diffusion region 12 may stop in the middle of third nitride semiconductor layer 6, as shown in FIG. 4, or may reach second nitride semiconductor layer 4 or first nitride semiconductor layer 3 further below third nitride layer 6 (not shown).

By diffusing a low concentration p-type impurity into third nitride semiconductor layer 6, second nitride semiconductor layer 4, and first nitride semiconductor layer 3, the resistance of each nitride semiconductor layer can be increased. In addition, since Mg can fill point defects in the nitride semiconductor layers, surface leakage and gate leakage when forming a nitride semiconductor device such as a field effect transistor (FET) can be reduced.

However, when the p-type impurity concentration in p-type impurity diffusion region 12 is too high, such as 5E18 cm⁻³ or higher, it becomes a p-type nitride semiconductor layer, resulting in a low resistance. In that case, surface leakage increases when FET and the like are formed, so it is desirable that the region other than directly under gate layer 7 out of p-type impurity diffusion region 12 with a p-type impurity concentration of 5E18 cm⁻³ or higher is removed by the aforementioned over-etching. That is, it is advisable that the p-type impurity concentration on the topmost surface side of p-type impurity diffusion region 12 in the region other than directly under gate layer 7 of p-type impurity diffusion region 12 is 5E18 cm⁻³ or less, desirably 1E18 cm⁻³ or less.

It should be noted that immediately after forming third nitride semiconductor layer 6, activation annealing is performed continuously at a high temperature of 1100° C. or higher in an MOCVD chamber (in-situ), and in this case, even if third nitride semiconductor layer 6 is a nitride semiconductor containing Al, which is resistant to thermal decomposition, it will thermally decompose to some extent from the surface side, causing the stoichiometry to collapse and the film to be thinned. By forming gate layer 7 after the activation annealing, the group III and group V elements that have been desorbed during the activation annealing can be resupplied to third nitride semiconductor layer 6, and this has the effect of improving the crystallinity of third nitride semiconductor layer 6.

By using this variation, in addition to the effects of the embodiment, Variation 1, and Variation 2, Mg can fill point defects in the nitride semiconductor layers. In addition, when forming gate layer 7, group III and group V elements that have been desorbed during activation annealing can be resupplied to third nitride semiconductor layer 6, and this has the effect of improving the crystallinity of third nitride semiconductor layer 6. Accordingly, surface leakage and gate leakage when forming a nitride semiconductor device such as a field effect transistor (FET) can be reduced.

### (Variation 4)

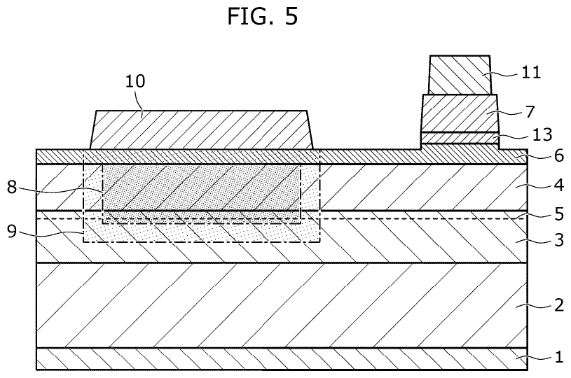

Next, FIG. 5 shows a cross-sectional structural diagram of a nitride semiconductor device according to Variation 4 of the embodiment, in which the ohmic electrode is in ohmic contact with the diffusion region, the damaged region, or both, and a fourth nitride semiconductor layer is included between the nitride semiconductor layer and the gate layer.

As shown in FIG. 5, this variation is different from the embodiment shown in FIG. 1 in including fourth nitride semiconductor layer 13 consisting of AlGaN (alternatively, for example, GaN, InGaN, AlGaN, AlN, AlInGaN, and the like, which are group III nitride semiconductors) on third nitride semiconductor layer 6. Fourth nitride semiconductor layer 13 includes a band gap larger than that of first nitride semiconductor layer 3 and is in direct contact with third nitride semiconductor layer 6.

It is desirable that two-dimensional electron gas is not formed at the interface with third nitride semiconductor layer 6 directly under fourth nitride semiconductor layer 13, as this may cause gate leakage when a field effect transistor is formed. For that reason, it is desirable that the band gap of fourth nitride semiconductor layer 13 is equal to or smaller than the band gap of third nitride semiconductor layer 6.

In addition, when fourth nitride semiconductor layer 13 is made of AlGaN, for example, the band gap is equal to or smaller than that of third nitride semiconductor layer 6, which also has the effect of lowering the Al composition and improving crystallinity. In addition, it is desirable that fourth nitride semiconductor layer 13 is also a nitride semiconductor which contains Al as third nitride semiconductor layer 6 is.

It should be noted that immediately after forming third nitride semiconductor layer 6, activation annealing is performed continuously at a high temperature of 1100° C. or higher in an MOCVD chamber (in-situ), and in this case, even if third nitride semiconductor layer 6 is a nitride semiconductor containing Al, which is resistant to thermal decomposition, it will decompose to some extent from the surface side, causing the stoichiometry to collapse and the film to be thinned. By forming fourth nitride semiconductor layer 13 after the activation annealing, group III and group V elements that have been desorbed during activation annealing can be resupplied to third nitride semiconductor layer 6, and this has the effect of improving the crystallinity of third nitride semiconductor layer 6. Therefore, it is desirable that fourth nitride semiconductor layer 13 has the same constituent elements as third nitride semiconductor layer 6. Specifically, when third nitride semiconductor layer 6 is made of AlGaN, it is desirable that fourth nitride semiconductor layer 13 is also made of AlGaN. In addition, as shown in FIG. 5 or as mentioned above, gate layer 7 may be formed continuously in the MOCVD chamber (in-situ) immediately after forming fourth nitride semiconductor layer 13.

By using this variation, in addition to the effects of Embodiment 1, Variation 1, Variation 2, and Variation 3, it is possible to improve the crystallinity of third nitride semiconductor layer 6 with stoichiometry collapse or film thinning due to activation annealing. Accordingly, surface leakage and gate leakage when forming a nitride semiconductor device such as a field effect transistor (FET) can be reduced.

When the embodiment and Variation 1 to Variation 4 are used as a nitride semiconductor device such as a field effect transistor (FET) or diode which has gate layer 7, gate electrode 11 is provided on gate layer 7 as shown in FIG. 1 to FIG. 5. Gate electrode 11 is only needed to be an electrode made of one or a combination of two or more metals such as Ti, Ni, Pd, Pt, Au, W, WSi, Ta, TiN, Al, Mo, Hf, and Zr. When gate layer 7 is a p-type group III nitride semiconductor, gate electrode 11 may be in ohmic contact or Schottky contact with gate layer 7. Since the reliability of gate electrode 11 is higher if it is in ohmic contact, it is desirable to use an electrode made of one or a combination of two or more metals with low contact resistance, such as Ni, Pt, Pd, Au, Ti, Cr, In, Sn, and Al. It should be noted that in the case of a field effect transistor (FET), ohmic electrode 10 needs to be spaced apart from gate layer 7 and formed on the left and right sides in the cross-sectional view shown in FIG. 1 to FIG. 5 (only the left side is shown in FIG. 1 to FIG. 5). In addition, when this structure is used as a normally-off-operating FET or the like, a recess structure may be provided in second nitride semiconductor layer 4 directly under gate layer 7 (not shown).

### Example 1 of Manufacturing Method

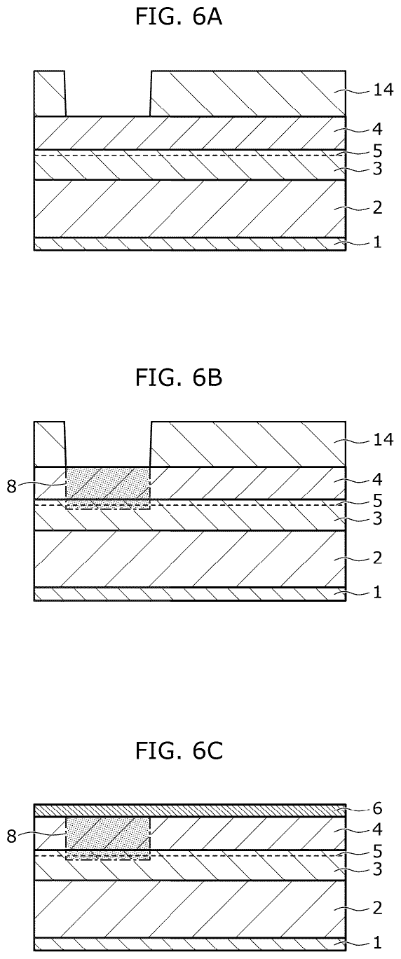

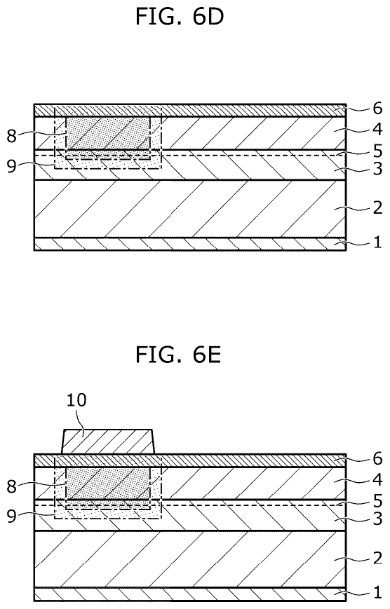

Next, FIG. 6A to FIG. 6E show cross-sectional views showing each step of the manufacturing method of the structure which does not include gate layer 7 and gate electrode 11 in the structure shown in FIG. 1 of the structure shown in FIG. 1, which does not have gate layer 7 or gate electrode 11. It should be noted that the present manufacturing method describes the minimum configuration, and is not limited thereto. In addition, the order of the present manufacturing method is not limited thereto.

First, suitable buffer layer 2 (for example, a single layer or multiple layers of group III nitride semiconductors, such as GaN, AlGaN, AlN, InGaN, InN, AlInGaN, and the like) is formed on suitable Si substrate 1 having (111) plane (alternatively, a substrate such as Sapphire, SiC, GaN, AlN, and the like) using the epitaxial growth technology such as known MOCVD methods. Next, first nitride semiconductor layer 3 consisting of GaN (alternatively, for example, a single layer or multiple layers of InGaN, InN, AlGaN, AlInGaN, and the like, which are group III nitride semiconductors) is formed on buffer layer 2. Next, second nitride semiconductor layer 4 consisting of AlGaN (alternatively, for example, GaN, InGaN, AlGaN, AlN, AlInGaN, and the like, which are group III nitride semiconductors) is formed on first nitride semiconductor layer 3. Such buffer layer 2, first nitride semiconductor layer 3, and second nitride semiconductor layer 4 are formed continuously. Second nitride semiconductor layer 4 includes a band gap larger than that of first nitride semiconductor layer 3, and is in direct contact with first nitride semiconductor layer 3. When second nitride semiconductor layer 4 consists of AlGaN and first nitride semiconductor layer 3 consists of GaN, due to (i) the piezoelectric charge generated by the difference in lattice constants between AlGaN and GaN and (ii) the difference in band gap, a high concentration of two-dimensional electron gas 5 is generated on the side of first nitride semiconductor layer 3 near the interface between second nitride semiconductor layer 4 and first nitride semiconductor layer 3.

Next, resist pattern 14 for forming damaged region 8 is formed using a known photolithography technology (FIG. 6A).

Next, damaged region 8 is formed by ion implantation from the surface side through resist pattern 14 on second nitride semiconductor layer 4 (FIG. 6B). In the ion implantation, Si (alternatively, Ge, or the like), which is an n-type impurity, is implanted. The lower end of this damaged region 8 may remain within second nitride semiconductor layer 4 in the depth direction (not shown). Alternatively, it may reach first nitride semiconductor layer 3 as shown in FIG. 1 and FIG. 6B. From the viewpoint of reducing the contact resistance of the nitride semiconductor device and the sheet resistance, it is desirable that two-dimensional electron gas 5 in first nitride semiconductor layer 3 is reached. It is desirable that the n-type impurity implanted into damaged region 8 is highly concentrated because the ions are implanted for the purpose of obtaining a low-resistance nitride semiconductor layer. Specifically, it is desirable that the concentration is 1E19 cm⁻³ or higher, and it is desirable that the peak concentration is 1E20 cm⁻³ or higher. The ion implantation conditions depend on the film thickness of the epitaxial structure used, but Si, which is an n-type impurity, is implanted at an energy of 10 keV to 50 keV to a depth of about 1E15 cm⁻² to 3E15 cm⁻². Accordingly, Si can be implanted to a depth of about 30 nm to 100 nm at a concentration of 1E18 cm⁻³ or more. At this time, the crystal lattice of damaged region 8 has collapsed due to ion implantation damage and has become amorphous.

Next, resist pattern 14 on second nitride semiconductor layer 4 including damaged region 8 is completely removed using a known ashing method, organic cleaning method, sulfuric acid-hydrogen peroxide mixture cleaning, or the like.

Subsequently, third nitride semiconductor layer 6 is formed on second nitride semiconductor layer 4 by MOCVD method or the like (FIG. 6C). It is desirable that third nitride semiconductor layer 6 is a nitride semiconductor containing Al to withstand thermal decomposition during activation annealing at the high temperatures described later, and also to withstand thermal decomposition by high temperatures and etching gases such as hydrogen when formed on second nitride semiconductor layer 4 by metal organic chemical vapor deposition (MOCVD) method or the like.

It is desirable that two-dimensional electron gas is not formed at the interface with second nitride semiconductor layer 4 directly under third nitride semiconductor layer 6, as this may cause gate leakage when a field effect transistor is formed. For that reason, it is desirable that the band gap of third nitride semiconductor layer 6 is equal to or smaller than the band gap of second nitride semiconductor layer 4. In addition, when third nitride semiconductor layer 6 is made of AlGaN, for example, the band gap is smaller than that of second nitride semiconductor layer 4, which also has the effect of lowering the Al composition and improving crystallinity.

Subsequently, activation annealing at a high temperature is performed in an MOCVD chamber (in-situ) immediately after the formation of third nitride semiconductor layer 6. Accordingly, diffusion region 9 is formed by diffusion of the n-type impurity added by ion implantation into damaged region 8 into the surrounding area (FIG. 6D). Activation annealing is performed to activate the ion-implanted n-type impurity. In order to activate the n-type impurity of the nitride semiconductor and to form diffusion region 9 in the vicinity of damaged region 8, activation annealing is usually performed at 1100° C. or higher, desirably 1150° C. or higher for about 5 to 30 minutes.

Diffusion region 9 is provided in all nitride semiconductor layers on the top, bottom, left, and right that are in contact with damage region 8, that is, in all of first nitride semiconductor layer 3, second nitride semiconductor layer 4, and third nitride semiconductor layer 6 in FIG. 6D. When the lower end of damaged region 8 stops in the middle of second nitride semiconductor layer 4 (not shown), diffusion region 9 may stop in second nitride semiconductor layer 4. From the viewpoint of reducing the contact resistance of the nitride semiconductor device and the sheet resistance, it is desirable that two-dimensional electron gas 5 of first nitride semiconductor layer 3 is reached from the inside of second nitride semiconductor layer 4.

It should be noted that diffusion region 9 is defined as a region that is in contact with damaged region 8 and in which an n-type impurity is diffused from damaged region 8, but here, more specifically, it is defined as a region where the concentration of an n-type impurity is 1E18 cm⁻³ or more. In addition, since the n-type impurity concentration in diffusion region 9 is diffused from damaged region 8, the n-type impurity concentration in diffusion region 9 is inevitably lower than that in damaged region 8. Specifically, since it is desirable that the peak concentration of damaged region 8 is 1E20 cm⁻³ or more, the n-type impurity concentration of diffusion region 9 is 1E20 cm⁻³ or less. This makes diffusion region 9 a nitride semiconductor with lower resistance, which helps reduce contact resistance and sheet resistance.

Diffusion region 9 has no or very little ion implantation damage in the downward and lateral directions among the upper, lower, left, and right sides that are in contact with damaged region 8. In addition, regarding third nitride semiconductor layer 6 located in the upper direction, Since third nitride semiconductor layer 6 is epitaxially grown by metal organic chemical vapor deposition (MOCVD) method or the like on top of damaged region 8, where the crystal lattice has collapsed and become slightly amorphous-like due to ion implantation damage, the crystallinity of diffusion region 9 directly above damaged region 8 is slightly poor.

Trimethylgallium (TMG) and trimethylaluminum (TMA), which are Group III raw materials, ammonia, which is a Group V raw material, and nitrogen and hydrogen, which are carrier gases, are supplied from the surface of damaged region 8 to damaged region 8 in the process of forming third nitride semiconductor layer 6. Accordingly, the crystallinity in damaged region 8 is restored to some extent, and does not become a completely amorphous structure but a slightly amorphous-like structure with better crystallinity. For that reason, the crystallinity of third nitride semiconductor layer 6, which grows directly above damaged region 8 whose crystallinity has been restored, is further improved. Furthermore, immediately after forming third nitride semiconductor layer 6, activation annealing is performed at a high temperature while flowing a gas such as ammonia, which is a group V raw material, or nitrogen, which is a carrier gas, in an MOCVD chamber (in-situ). For this reason, the slightly amorphous-like crystallinity of damaged region 8 can be further restored, and the crystallinity of third nitride semiconductor layer 6 directly above it can also be further restored.

Subsequently, ohmic electrode 10 is formed on third nitride semiconductor layer 6 on damaged region 8 by known photolithography technology, vapor deposition technology, lift-off technology, sputtering technology, dry etching technology, annealing (alloying) technology, and the like (FIG. 6E). Ohmic electrode 10 consists of an electrode made of one or a combination of two or more metals such as Ti, Al, Mo, and Hf that make ohmic contact with the nitride semiconductor layer. Ohmic electrode 10 is in direct contact with diffusion region 9 in third nitride semiconductor layer 6 and is electrically connected to two-dimensional electron gas 5. Since diffusion region 9 in third nitride semiconductor layer 6 directly above damaged region 8 has little crystal damage, the contact resistance of ohmic electrode 10 becomes small. In addition, as shown in FIG. 6E, the end of ohmic electrode 10 also comes into ohmic contact with diffusion region 9, which has very good crystallinity and is not directly above damaged region 8, so that the contact resistance is further reduced.

The effects of the present manufacturing method will be explained. By using the present manufacturing method, the contact resistance of ohmic electrode 10 is reduced, the sheet resistance from ohmic electrode 10 to two-dimensional electron gas 5 is also reduced, and as a result, it becomes possible to significantly reduce the on-resistance of the nitride semiconductor device (FET and the like) and significantly increase the maximum drain current. In addition, since activation annealing is performed continuously in-situ immediately after forming third nitride semiconductor layer 6 by regrowth, it is possible to prevent C contamination on the crystal surface, pile-up of Si, and the like, reduce the surface level, and reduce the gate leakage current. In addition, at the same time, the ion implantation restores the crystallinity of damaged region 8, which had become an amorphous crystal, making it possible to reduce gate leakage current.

### Example 2 of Manufacturing Method

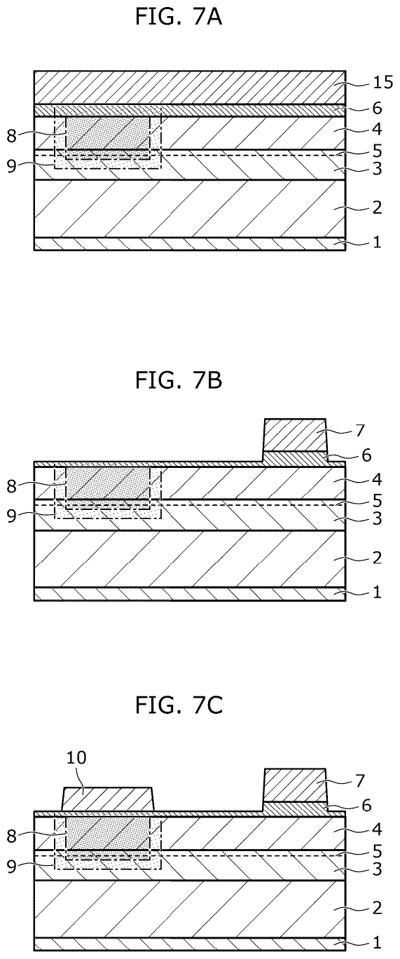

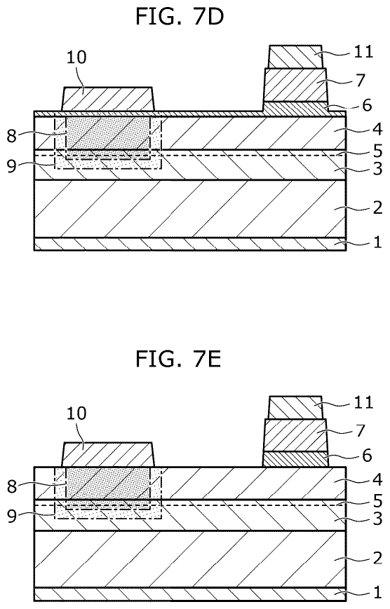

Next, FIG. 7A to FIG. 7E show cross-sectional views showing each step of the manufacturing method of the structure which includes gate layer 7 and gate electrode 11 in the structure shown in FIG. 1. It should be noted that the present manufacturing method describes the minimum configuration, and is not limited thereto. In addition, the order of the present manufacturing method is not limited thereto.

The present manufacturing method is the same up to FIG. 6D as Example 1 of the manufacturing method shown in FIG. 6A to FIG. 6E. Immediately after forming third nitride semiconductor layer 6 by regrowth using MOCVD technology or the like, activation annealing is performed continuously in-situ, and then, continuously further in the MOCVD chamber (in-situ), fifth nitride semiconductor layer 15 which contains a p-type impurity (Mg, Zn, C, or the like) consisting of p-GaN (alternatively, for example, p-InGaN, p-InN, p-AlGaN, p-AlInGaN, or the like, which is a group III nitride semiconductor) is formed (FIG. 7A). The p-type impurity of fifth nitride semiconductor layer 15 is doped to the concentration of 1E19 cm⁻³ or more, and if possible, 5E19 cm⁻³ or more to make it p-type.

After forming fifth nitride semiconductor layer 15 on third nitride semiconductor layer 6, gate layer 7 is formed by forming a resist pattern using a known lithography method, and performing selective dry etching using inductively coupled plasma reactive ion etching (ICP-RIE) method or the like (FIG. 7B). Even if selective dry etching is performed, the selectivity is not infinite, so over-etching of several nm to several tens of nm is generated as shown in FIG. 7B. For example, when the regrowth thickness of third nitride semiconductor layer 6 is about 20 nm, over-etching may be stopped in the middle of third nitride semiconductor layer 6 as shown in FIG. 7B. Alternatively, as shown in FIG. 7E, third nitride semiconductor layer 6 other than directly under gate layer 7 may be completely removed by over-etching by about 20 nm. Furthermore, over-etching may be applied to completely dig into second nitride semiconductor layer 4 (not shown).

As shown in the nitride semiconductor device according to Variation 3 of the embodiment (FIG. 4), after the growth of third nitride semiconductor layer 6, by continuously forming fifth nitride semiconductor layer 15 containing a p-type impurity (such as Mg, Zn, and C) consisting of p-GaN, the p-type impurity is diffused into third nitride semiconductor layer 6 to generate p-type impurity diffusion region 12 as shown in FIG. 4 (not shown in FIG. 7B to FIG. 7D). When the p-type impurity concentration in this p-type impurity diffusion region 12 is too high, such as 5E18 cm⁻³ or higher, it becomes a p-type nitride semiconductor layer, and p-type impurity diffusion region 12 results in a low resistance. In that case, surface leakage increases when FET and the like are formed, so it is desirable that the region other than directly under gate layer 7 out of p-type impurity diffusion region 12 with a p-type impurity concentration of 5E18 cm⁻³ or higher is removed by the aforementioned over-etching. That is, it is desirable that the p-type impurity concentration on the topmost surface side of p-type impurity diffusion region 12 in the region other than directly under gate layer 7 of p-type impurity diffusion region 12 is 5E18 cm⁻³ or less.

It should be noted that immediately after forming third nitride semiconductor layer 6, activation annealing is performed continuously at a high temperature in an MOCVD chamber (in-situ). In this case, even if third nitride semiconductor layer 6 is a nitride semiconductor containing Al, which is resistant to thermal decomposition, it will thermally decompose to some extent from the surface side, causing the stoichiometry to collapse and the film to be thinned. By forming fifth nitride semiconductor layer 15 after the activation annealing, group III and group V elements that have been desorbed during activation annealing can be resupplied to third nitride semiconductor layer 6, and this has the effect of improving the crystallinity of third nitride semiconductor layer 6.

After gate layer 7 is formed, activation annealing of the p-type impurity is performed at 700° C. to 900° C. for about 10 to 60 minutes in a gas atmosphere such as nitrogen using a known annealing technique. Accordingly, around 1% of the p-type impurity is activated, and gate layer 7 becomes p-type.

Subsequently, ohmic electrode 10 is formed on third nitride semiconductor layer 6 on damaged region 8 separated from gate layer 7 by known photolithography, deposition, lift-off, sputtering, dry etching, annealing (alloying) techniques or the like (FIG. 7C). Ohmic electrode 10 consists of an electrode made of one or a combination of two or more metals such as Ti, Al, Mo, Hf, and the like that makes ohmic contact with the nitride semiconductor layer, and is in direct contact with diffusion region 9 in third nitride semiconductor layer 6 and electrically connected to two-dimensional electron gas 5. Since diffusion region 9 in third nitride semiconductor layer 6 directly above damaged region 8 has little crystal damage, the contact resistance of ohmic electrode 10 becomes small. In addition, as shown in FIG. 7C, the end of ohmic electrode 10 also comes into ohmic contact with diffusion region 9, which has very good crystallinity and is not directly above damaged region 8, so that the contact resistance is further reduced.

It should be noted that as shown in FIG. 7E, by over-etching fifth nitride semiconductor layer 15 and completely removing third nitride semiconductor layer 6, ohmic electrode 10 can make direct ohmic contact with damaged region 8, which contains a higher concentration of the n-type impurity and has a lower resistance. This reduces contact resistance. It should be noted that contact resistance can be reduced by contacting ohmic electrode 10 with a nitride semiconductor layer having as low resistance as possible. For this reason, it is desirable that the electrode end of ohmic electrode 10 is located inside the end of damaged region 8 or inside the diffusion region 9 (FIG. 7C), but of course the electrode end of ohmic electrode 10 may be outside the end of damaged region 8 (not shown).

Finally, gate electrode 11 is formed using known photolithography technology, vapor deposition technology, lift-off technology, sputtering technology, dry etching technology, and the like (FIG. 7D or FIG. 7E). Gate electrode 11 is only needed to be an electrode made of one or a combination of two or more metals such as Ti, Ni, Pd, Pt, Au, W, WSi, Ta, TiN, Al, Mo, Hf, and Zr. However, although gate electrode 11 may be in ohmic contact or Schottky contact with gate layer 7, the reliability of the gate electrode is higher if it is in ohmic contact. For this reason, it is desirable to use an electrode made of one or a combination of two or more metals with low contact resistance, such as Ni, Pt, Pd, Au, Ti, Cr, In, Sn, and Al.

By using this variation, in addition to the effects of the manufacturing method shown in FIG. 6A to FIG. 6E, Mg added to fifth nitride semiconductor layer 15 can fill point defects in third nitride semiconductor layer 6. In addition, when forming fifth nitride semiconductor layer 15, group III and group V elements that have been desorbed during activation annealing can be resupplied to third nitride semiconductor layer 6, and this has the effect of improving the crystallinity of third nitride semiconductor layer 6. Accordingly, surface leakage and gate leakage when forming a nitride semiconductor device such as a field effect transistor (FET) can be reduced.

### Example 3 of Manufacturing Method

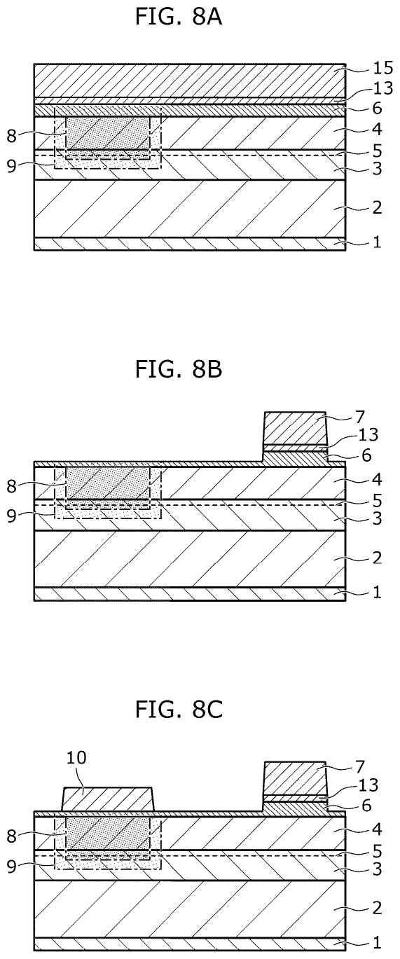

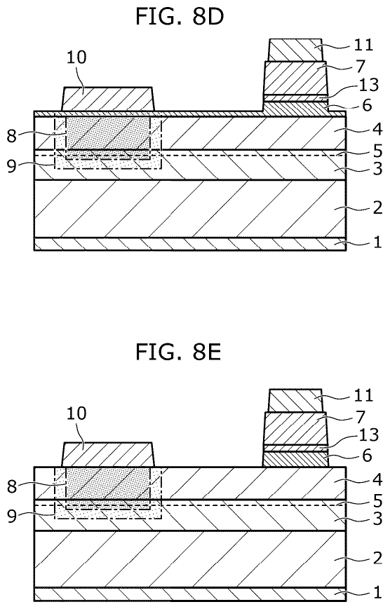

Next, cross-sectional views showing a manufacturing method of the structure shown in FIG. 5 are shown in FIG. 8A to FIG. 8E. It should be noted that the present manufacturing method describes the minimum configuration, and is not limited thereto. In addition, the order of the present manufacturing method is not limited thereto.

The present manufacturing method is basically almost the same as Example 2 of the manufacturing method shown in FIG. 6A to FIG. 6D and FIG. 7A to FIG. 7E, but is different in that fourth nitride semiconductor layer 13 is formed between third nitride semiconductor layer 6 and fifth nitride semiconductor layer 15.

Specifically, the present manufacturing method is the same up to FIG. 6D as Example 2 of the manufacturing method shown in FIG. 6A to FIG. 6D and FIG. 7A to FIG. 7E. Immediately after forming third nitride semiconductor layer 6 by regrowth using MOCVD technology or the like, activation annealing is performed continuously in-situ, and then, continuously further in the MOCVD chamber (in-situ), fourth nitride semiconductor layer 13 consisting of AlGaN (alternatively, for example, group III nitride semiconductors such as GaN, InGaN, AlGaN, AlN, AlInGaN, or the like) is formed. Furthermore, continuously in-situ, fifth nitride semiconductor layer 15 which contains a p-type impurity (Mg, Zn, C, or the like) consisting of p-GaN (alternatively, for example, p-InGaN, p-InN, p-AlGaN, p-AlInGaN, or the like, which is a group III nitride semiconductor) is formed (FIG. 8A).

Fourth nitride semiconductor layer 13 includes a band gap larger than that of first nitride semiconductor layer 3 and is in direct contact with third nitride semiconductor layer 6.

It is desirable that two-dimensional electron gas is not formed at the interface with third nitride semiconductor layer 6 directly under fourth nitride semiconductor layer 13, as this may cause gate leakage when a field effect transistor is formed. For that reason, it is desirable that the band gap of fourth nitride semiconductor layer 13 is equal to or smaller than the band gap of third nitride semiconductor layer 6.

In addition, when fourth nitride semiconductor layer 13 is made of AlGaN, for example, the band gap is equal to or smaller than that of third nitride semiconductor layer 6, which also has the effect of lowering the Al composition and improving crystallinity. In addition, it is desirable that fourth nitride semiconductor layer 13 is also a nitride semiconductor which contains Al as third nitride semiconductor layer 6 is.

It should be noted that immediately after forming third nitride semiconductor layer 6, activation annealing is performed continuously at a high temperature of 1000° C. or higher in an MOCVD chamber (in-situ). In this case, even if third nitride semiconductor layer 6 is a nitride semiconductor containing Al, which is resistant to thermal decomposition, it will thermally decompose to some extent from the surface side, causing the stoichiometry to collapse and the film to be thinned. By forming fourth nitride semiconductor layer 13 after the activation annealing, group III and group V elements that have been desorbed during activation annealing can be resupplied to third nitride semiconductor layer 6, and this has the effect of improving the crystallinity of third nitride semiconductor layer 6. Therefore, it is desirable that fourth nitride semiconductor layer 13 has the same constituent elements as third nitride semiconductor layer 6. Specifically, when third nitride semiconductor layer 6 is made of AlGaN which contains Al, it is desirable that fourth nitride semiconductor layer 13 is also made of AlGaN which contains Al.

In addition, as shown in FIG. 8A, since fourth nitride semiconductor layer 13 is formed after activation annealing, diffusion region 9 almost does not reach fourth nitride semiconductor layer 13 due to the growth temperature. That is, the growth temperature of fourth nitride semiconductor layer 13 is lower than the activation annealing temperature by 100° C. or more. However, depending on the growth temperature of fourth nitride semiconductor layer 13, diffusion region 9 may extend into fourth nitride semiconductor layer 13 (not shown).

Fifth nitride semiconductor layer 15 consists of p-GaN and contains a p-type impurity (Mg, Zn, C, or the like). The p-type impurity is doped to the concentration of 1E19 cm⁻³ or more, and if possible, 5E19 cm⁻³ or more to make it p-type.

After forming fifth nitride semiconductor layer 15 and fourth nitride semiconductor layer 13 on third nitride semiconductor layer 6, gate layer 7 is formed by forming a resist pattern using a known lithography method, and performing selective dry etching using inductively coupled plasma reactive ion etching (ICP-RIE) method or the like (FIG. 8B). Even if selective dry etching is performed, the selectivity is not infinite, so over-etching of several nm to several tens of nm is generated as shown in FIG. 8B. For example, when the regrowth film thicknesses of third nitride semiconductor layer 6 and fourth nitride semiconductor layer 13 are totally about 20 nm, over-etching may be stopped in the middle of third nitride semiconductor layer 6 as shown in FIG. 8B. Alternatively, over-etching may be stopped in the middle of fourth nitride semiconductor layer 13 (not shown). Alternatively, as shown in FIG. 8E, fourth nitride semiconductor layer 13 and third nitride semiconductor layer 6, other than directly under gate layer 7 may be completely removed by over-etching by about 20 nm. Furthermore, over-etching may be applied to completely dig into second nitride semiconductor layer 4 (not shown).

As shown in the nitride semiconductor device according to Variation 3 of the embodiment (FIG. 4), after the growth of third nitride semiconductor layer 6 and fourth nitride semiconductor layer 13, by continuously forming fifth nitride semiconductor layer 15 containing a p-type impurity (such as Mg, Zn, and C) consisting of p-GaN, the p-type impurity is diffused into fourth nitride semiconductor layer 13 and third nitride semiconductor layer 6 to generate p-type impurity diffusion region 12 (not shown). When the p-type impurity concentration in this p-type impurity diffusion region 12 is too high, such as 5E18 cm⁻³ or higher, it becomes a p-type nitride semiconductor layer, and p-type impurity diffusion region 12 results in a low resistance. In that case, surface leakage increases when FET and the like are formed, so it is desirable that the region other than directly under gate layer 7 out of p-type impurity diffusion region 12 with a p-type impurity concentration of 5E18 cm⁻³ or higher is removed by the aforementioned over-etching. That is, it is desirable that the p-type impurity concentration on the topmost surface side of p-type impurity diffusion region 12 in the region other than directly under gate layer 7 of p-type impurity diffusion region 12 is 5E18 cm⁻³ or less.

It should be noted that immediately after forming third nitride semiconductor layer 6, activation annealing is performed continuously at high temperature in an MOCVD chamber (in-situ). At this time, even if third nitride semiconductor layer 6 is a nitride semiconductor containing Al, which is resistant to thermal decomposition, it will thermally decompose from the surface side to some extent, resulting in stoichiometry collapse and film thinning. By forming fourth nitride semiconductor layer 13 after the activation annealing, group III and group V elements that have been desorbed during activation annealing can be resupplied to third nitride semiconductor layer 6, and this has the effect of improving the crystallinity of third nitride semiconductor layer 6.

After gate layer 7 is formed, activation annealing of the p-type impurity is performed at 700° C. to 900° C. for about 10 to 60 minutes in a gas atmosphere such as nitrogen using a known annealing technique. Accordingly, around 1% of the p-type impurity is activated, and gate layer 7 becomes p-type.

Subsequently, ohmic electrode 10 is formed on third nitride semiconductor layer 6 on damaged region 8 separated from gate layer 7 by known photolithography, deposition, lift-off, sputtering, dry etching, annealing (alloying) techniques or the like (FIG. 8C). Ohmic electrode 10 consists of an electrode made of one or a combination of two or more metals such as Ti, Al, Mo, Hf, and the like that makes ohmic contact with the nitride semiconductor layer, and is in direct contact with diffusion region 9 in third nitride semiconductor layer 6 and electrically connected to two-dimensional electron gas 5. Since diffusion region 9 in third nitride semiconductor layer 6 directly above damaged region 8 has little crystal damage, the contact resistance of ohmic electrode 10 becomes small. In addition, as shown in FIG. 8C, the end of ohmic electrode 10 also comes into ohmic contact with diffusion region 9, which has very good crystallinity and is not directly above damaged region 8, so that the contact resistance is further reduced.

It should be noted that as shown in FIG. 8E, by over-etching fifth nitride semiconductor layer 15 and completely removing fourth nitride semiconductor layer 13 and third nitride semiconductor layer 6, ohmic electrode 10 can make direct ohmic contact with damaged region 8, which contains a higher concentration of the n-type impurity and has a lower resistance. This reduces contact resistance. It should be noted that contact resistance can be reduced by contacting ohmic electrode 10 with a nitride semiconductor layer having as low resistance as possible. For this reason, it is desirable that the electrode end of ohmic electrode 10 is located at least inside the end of damaged region 8, and if possible, inside diffusion region 9.

Finally, gate electrode 11 is formed using known photolithography technology, vapor deposition technology, lift-off technology, sputtering technology, dry etching technology, and the like (FIG. 8D or FIG. 8E). Gate electrode 11 is only needed to be an electrode made of one or a combination of two or more metals such as Ti, Ni, Pd, Pt, Au, W, WSi, Ta, TiN, Al, Mo, Hf, and Zr. However, although gate electrode 11 may be in ohmic contact or Schottky contact with gate layer 7, the reliability of the gate electrode is higher if it is in ohmic contact. For this reason, it is desirable to use an electrode made of one or a combination of two or more metals with low contact resistance, such as Ni, Pt, Pd, Au, Ti, Cr, In, Sn, and Al.

In addition to the effects of the manufacturing method shown in FIG. 7A to FIG. 7E, using this variation has such an effect that when forming fourth nitride semiconductor layer 13, it is possible to resupply Group III and Group V elements to third nitride semiconductor layer 6 with stoichiometry collapse or film thinning due to activation annealing when forming fourth nitride semiconductor layer 13, thereby improving the crystallinity of third nitride semiconductor layer 6. Accordingly, surface leakage and gate leakage when forming a nitride semiconductor device such as a field effect transistor (FET) can be reduced.

### (Growth Profile)

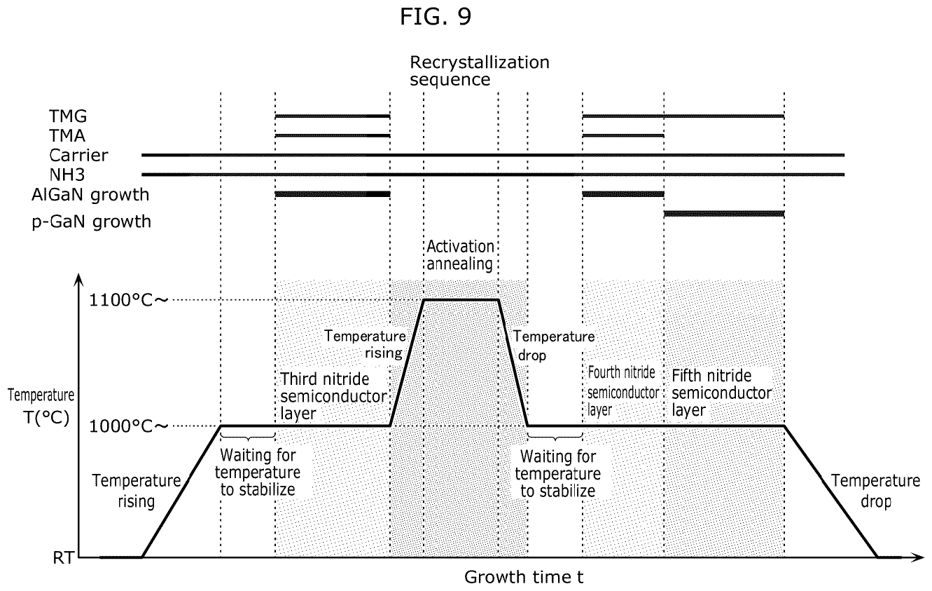

Next, FIG. 9 shows the temperature and gas growth profiles for the continuous formation steps of third nitride semiconductor layer 6, activation annealing, fourth nitride semiconductor layer 13, and fifth nitride semiconductor layer 15 in the manufacturing method described above. It should be noted that this manufacturing method describes the minimum configuration, and is not limited thereto. In addition, the order of the present manufacturing method is not limited thereto.

The epitaxial wafer on which up to second nitride semiconductor layer 4 has been formed is subjected to an appropriate process, followed by an appropriate cleaning process, and then regrown in MOCVD. During regrowth, carrier gas (hydrogen or nitrogen, or both) and ammonia gas are kept flowing as needed.

First, the temperature is raised to the growth temperature of third nitride semiconductor layer 6 (around 1000° C.). In order to suppress the decomposition of second nitride semiconductor layer 4 when the temperature is raised, it is desirable that the carrier gas is mainly nitrogen containing as little hydrogen being an etching gas as possible, or is 100% nitrogen. Subsequently, after an appropriate temperature stabilization time, third nitride semiconductor layer 6 made of AlGaN is epitaxially grown by trimethyl gallium (TMG) or trimethyl aluminum (TMA), which is a group III element source, and ammonia, which is a group V source. Subsequently, in a carrier gas or ammonia gas atmosphere, activation annealing is performed at a temperature of 1100° C. or higher, desirably 1150° C. or higher, for about 5 to 30 minutes. In order to suppress decomposition of second nitride semiconductor layer 4, it is desirable that the carrier gas during the activation annealing and its temperature raising/lowering is mainly nitrogen containing as little hydrogen being an etching gas as possible, or is 100% nitrogen. Example 1 of the manufacturing method shown in FIG. 6A to FIG. 6E is completed by lowering the temperature after activation annealing.

In the Example 3 of the manufacturing method shown in FIG. 8A to FIG. 8E, the temperature is lowered to around 1000° C. after activation annealing, and after an appropriate temperature stabilization time period, fourth nitride semiconductor layer 13 and fifth nitride semiconductor layer 15 are continuously formed in-situ. Since fourth nitride semiconductor layer 13 is made of AlGaN, it is epitaxially grown by flowing TMG or TMA which is a group III element source, and ammonia which is a group V source. Since fifth nitride semiconductor layer 15 is made of p-GaN, it is epitaxially grown by flowing TMG which is a group III element source, ammonia which is a group V source, and bis(cyclopentadienyl) magnesium (Cp2Mg) which becomes a p-type impurity (FIG. 8A). The epitaxial growth temperatures of fourth nitride semiconductor layer 13 and fifth nitride semiconductor layer 15 need not be the same at all, but may be grown at different temperatures. Thereafter, the temperature is lowered to the MOCVD take-out temperature and the process is completed.

It should be noted that Example 2 of the manufacturing method shown in FIG. 7A to FIG. 7E is different in that fifth nitride semiconductor layer 15 is grown without growing fourth nitride semiconductor layer 13 in the growth profile in FIG. 9 described above.

### Others

Although the nitride semiconductor device according to one or more aspects has been described above based on the embodiment, the present disclosure is not limited thereto. Forms obtained by applying various modifications to the present embodiment conceived by a person skilled in the art and forms realized by arbitrarily combining the components in different embodiments without departing from the spirit of the present disclosure are also included in this disclosure.

In addition, various changes, substitutions, additions, omissions, and the like can be made to each of the above embodiments within the scope of the claims or equivalents thereof.

### INDUSTRIAL APPLICABILITY

The present disclosure can reduce the on-resistance of a semiconductor device and increase the maximum drain current, thereby improving the performance of a power device.

1. A nitride semiconductor device comprising:
a substrate;
a first nitride semiconductor layer provided over the substrate;
a second nitride semiconductor layer that is on the first nitride semiconductor layer and includes a band gap larger than a band gap of the first nitride semiconductor layer; and
a third nitride semiconductor layer that is on the second nitride semiconductor layer and includes a band gap larger than the band gap of the first nitride semiconductor layer,
wherein the second nitride semiconductor layer includes a damaged region in which an n-type impurity is selectively added by ion implantation,
a diffusion region in which the n-type impurity is diffused is present in a vicinity of the damaged region, and
the nitride semiconductor device further comprises:
an ohmic electrode provided above the damaged region, and the ohmic electrode is in ohmic contact with the diffusion region.

2. A nitride semiconductor device comprising:
a substrate;
a first nitride semiconductor layer provided over the substrate;
a second nitride semiconductor layer that is on the first nitride semiconductor layer and includes a band gap larger than a band gap of the first nitride semiconductor layer; and
a third nitride semiconductor layer that is on the second nitride semiconductor layer and includes a band gap larger than the band gap of the first nitride semiconductor layer,
wherein the second nitride semiconductor layer includes a damaged region in which an n-type impurity is selectively added by ion implantation,
a diffusion region in which the n-type impurity is diffused is present in a vicinity of the damaged region, and
the nitride semiconductor device further comprises:
an ohmic electrode provided above the damaged region, and the ohmic electrode is in ohmic contact with the damaged region.

3. The nitride semiconductor device according to claim 1,
wherein the ohmic electrode is also in contact with the damaged region.

4. The nitride semiconductor device according to claim 1,
wherein the third nitride semiconductor layer contains Al.

5. The nitride semiconductor device according to claim 1,
wherein the second nitride semiconductor layer contains Al.

6. The nitride semiconductor device according to claim 1,
wherein a peak concentration of a n-type impurity added to the third nitride semiconductor layer is lower than a peak concentration of the n-type impurity added to the second nitride semiconductor layer.

7. The nitride semiconductor device according to claim 1,
wherein the band gap of the third nitride semiconductor layer is less than or equal to the band gap of the second nitride semiconductor layer.

8. The nitride semiconductor device according to claim 1,
wherein a peak concentration of the n-type impurity added to the second nitride semiconductor layer is 1E20 cm⁻³ or more.

9. The nitride semiconductor device according to claim 1,
wherein a peak concentration of a n-type impurity added to the third nitride semiconductor layer is 1E20 cm⁻³ or less.

10. The nitride semiconductor device according to claim 1,
wherein the n-type impurity is Si.

11. The nitride semiconductor device according to claim 1,
wherein an end of the ohmic electrode that is in contact with a nitride semiconductor is in an inner side of the diffusion region.

12. The nitride semiconductor device according to claim 1,
wherein the third nitride semiconductor layer contains a p-type impurity.

13. The nitride semiconductor device according to claim 1,
wherein the second nitride semiconductor layer contains a p-type impurity.

14. A manufacturing method for a nitride semiconductor device, the manufacturing method comprising:
ion-implanting an n-type impurity into a second nitride semiconductor layer provided over a substrate in a semiconductor stack;
forming a third nitride semiconductor layer on the second nitride semiconductor layer;
performing activation annealing for the n-type impurity at 1000° C. or higher; and
forming a fourth nitride semiconductor layer on the third nitride semiconductor layer,
wherein the activation annealing is performed in-situ after the forming of the third nitride semiconductor layer and before the forming of the fourth nitride semiconductor layer.

15. The manufacturing method for the nitride semiconductor device according to claim 14,
wherein the third nitride semiconductor layer contains Al.

16. The manufacturing method for the nitride semiconductor device according to claim 14,
wherein the fourth nitride semiconductor layer contains Al.

17. The manufacturing method for the nitride semiconductor device according to claim 14, further comprising:
laminating a p-type fifth nitride semiconductor layer on the fourth nitride semiconductor layer.

18. The manufacturing method for the nitride semiconductor device according to claim 14,
wherein nitrogen gas is used as part of a gas atmosphere during the activation annealing.

19. The manufacturing method for the nitride semiconductor device according to claim 14,
wherein ammonia gas is used as part of a gas atmosphere during the activation annealing.
